(19) United States
(12) Patent Application Publication
(10) Pub. No.: US 2024/0395589 A1
(43) Pub. Date: Nov. 28, 2024

(54) SUBSTRATE PROCESSING APPARATUS AND METHOD OF ADJUSTING SUBSTRATE TRANSFER POSITION

(71) Applicant: Tokyo Electron Limited, Tokyo (JP)

(72) Inventors: Shota UMEZAKI, Kumamoto (JP); Kouji KIMOTO, Kumamoto (JP); Masato OZEKI, Kumamoto (JP); Ryosuke KENZAKI, Kumamoto (JP)

(73) Assignee: Tokyo Electron Limited, Tokyo (JP)

(21) Appl. No.: 18/672,505

(22) Filed: May 23, 2024

(30) Foreign Application Priority Data
May 24, 2023 (JP) 2023-085154

(51) Int. Cl. H01L 21/677; B23Q 7/10; B23Q 7/14; H01L 21/67

(52) U.S. Cl. CPC H01L 21/67742; B23Q 7/103; B23Q 7/1431; H01L 21/67253

(57) ABSTRACT

A substrate processing apparatus includes a process mechanism that processes a substrate. The process mechanism includes: a processing container that accommodates therein the substrate; a first supporting member that horizontally supports the substrate; and a second supporting member that horizontally supports the substrate at an outside of the processing container. The first supporting member and the second supporting member support the substrate such that a center axis of the substrate in the processing container and a center axis of the substrate at an outside of the processing container match, in a case where at least viewed from a direction where the substrate is carried-in to the container and carried-out from the container.

### CROSS-REFERENCE TO RELATED APPLICATION

The present application claims priority to and incorporates by reference the entire contents of Japanese Patent Application No. 2023-085154 filed in Japan on May 24, 2023.

### FIELD

Exemplary embodiment disclosed herein relates to a substrate processing apparatus and a method of adjusting a substrate transfer position.

### BACKGROUND

Conventionally, there has been known a supercritical drying process for drying a substrate by forming a liquid film for preventing the substrate from drying on a surface of the substrate and contacting a supercritical fluid to the substrate on which the liquid film is formed.

A drying unit for executing a supercritical drying process for a substrate on which a liquid film is formed and an inspection unit for inspecting a covering state of the liquid film on the substrate are arranged to contact in the vertical direction as a substrate processing apparatus for executing the supercritical drying process according to Japanese Laid-open Patent Publication No. 2022-30851.

The present disclosure provides a technique capable of reducing the relative displacement of the substrate between the inside and the outside of the processing container.

### SUMMARY

A substrate processing apparatus according to one aspect of the present disclosure includes: a process unit that includes: a processing container that accommodates therein a substrate; a first supporting member that horizontally supports the substrate in the processing container; and a second supporting member that horizontally supports the substrate at an outside of the processing container, wherein the first supporting member and the second supporting member support the substrate such that a center axis of the substrate in the processing container and a center axis of the substrate at an outside of the processing container match, in a case where at least viewed from a direction where the substrate is carried-in to the container and carried-out from the container.

### BRIEF DESCRIPTION OF DRAWINGS

FIG. 1 is a schematic cross-sectional view of a substrate processing system viewed from the above of the system according to an embodiment;

FIG. 2 is a schematic cross-sectional view of the substrate processing system viewed from the side of the system according to the embodiment;

FIG. 3 is a flowchart illustrating a series of substrate processing procedures to be executed in the substrate processing system according to the embodiment;

FIG. 4 is a diagram illustrating procedures of a wafer transfer according to the embodiment;

FIG. 5 is a diagram illustrating a configuration example of a liquid processing unit according to the embodiment;

FIG. 6 is a schematic cross-sectional view illustrating a configuration of a measurement unit (i.e., measurer) and a drying unit (i.e., dryer) according to the embodiment;

FIG. 7 is a schematic cross-sectional view illustrating one example of a state where a wafer is housed in a processing container of the drying unit according to the embodiment;

FIG. 8 is a schematic cross-sectional side view of the processing container of the drying unit viewed from the side of an opening of the processing container according to the embodiment;

FIG. 9 is a flowchart illustrating a procedure of a series of operations to be executed by the substrate processing system according to the embodiment;

FIG. 10A is an operation explanatory illustration illustrating another example of a transfer position adjusting process to be executed by the substrate processing system according to the embodiment;

FIG. 10B is an operation explanatory illustration illustrating another example of a transfer position adjusting process to be executed by the substrate processing system according to the embodiment;

FIG. 10C is an operation explanatory illustration illustrating another example of a transfer position adjusting process to be executed by the substrate processing system according to the embodiment;

FIG. 10D is an operation explanatory illustration illustrating another example of a transfer position adjusting process to be executed by the substrate processing system according to the embodiment;

FIG. 10E is an operation explanatory illustration illustrating another example of a transfer position adjusting process to be executed by the substrate processing system according to the embodiment; and

FIG. 10F is an operation explanatory illustration illustrating another example of a transfer position adjusting process to be executed by the substrate processing system according to the embodiment.

### DESCRIPTION OF EMBODIMENT

An exemplary embodiment of a substrate processing apparatus and a method of adjusting a substrate transfer position disclosed in the present application (hereinafter referred to as “embodiment”) will be described below in detail with reference to the accompanying drawings. The present invention is not limited to the embodiment explained below. It's to be noted that the drawings are schematic and the size and the ratio between the elements may be different from the real ones. Furthermore, the size and the ratio may be different between the drawings, too.

In the embodiment described below, the same sign is assigned to the same part, and a duplicated explanation is omitted. In the referenced drawings, a rectangular coordinate system prescribed with X-axis, Y-axis and Z-axis directions may be used in such a manner that the positive Z-axis direction is oriented upward vertically to help to understand the embodiment.

Conventionally, there has been known a supercritical drying process for drying a substrate by forming a liquid film for preventing the substrate from drying on a surface of the substrate and contacting a supercritical fluid to the substrate on which the liquid film is formed.

A drying unit for executing a supercritical drying process for a substrate on which a liquid film is formed and an inspection unit for inspecting a covering state of the liquid film on the substrate are arranged to contact in the vertical direction as a substrate processing apparatus for executing the supercritical drying process according to the Patent Literature 1.

However, the above-mentioned prior art may be improved to reduce a displacement between the relative positions of the substrate in and out of the processing container.

For example, according to the substrate processing apparatus disclosed in the Patent Literature 1, the substrate on which a liquid film is formed is transferred to the inspection unit and the drying unit in this order. If the position of the substrate inside the processing container of the drying unit and the position of the substrate outside the processing container of the drying unit are relatively displaced from each other, the substrate on which the liquid film is formed may not be transferred appropriately into the processing container of the drying unit. Such inappropriate transfer of the substrate may cause a problem for the supercritical drying process.

Accordingly, people are expecting a technology that can reduce the relative displacement of the substrate between the inside and the outside of the processing container.

### Configuration of Substrate Processing System

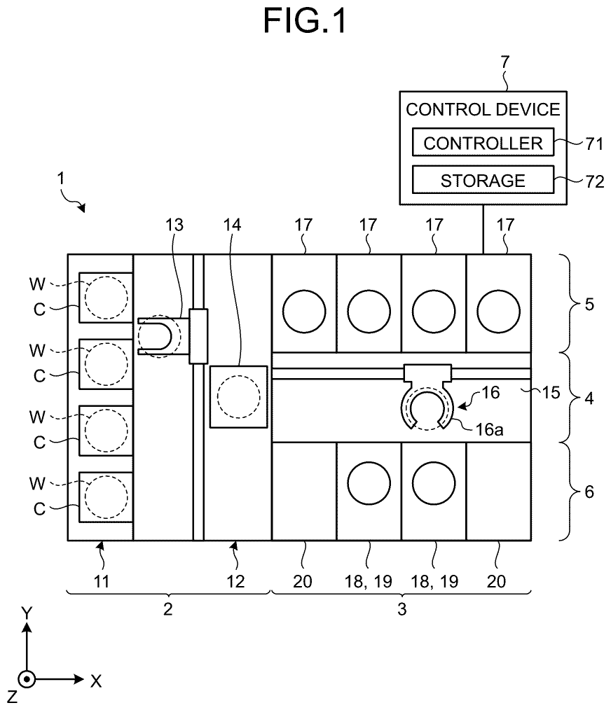

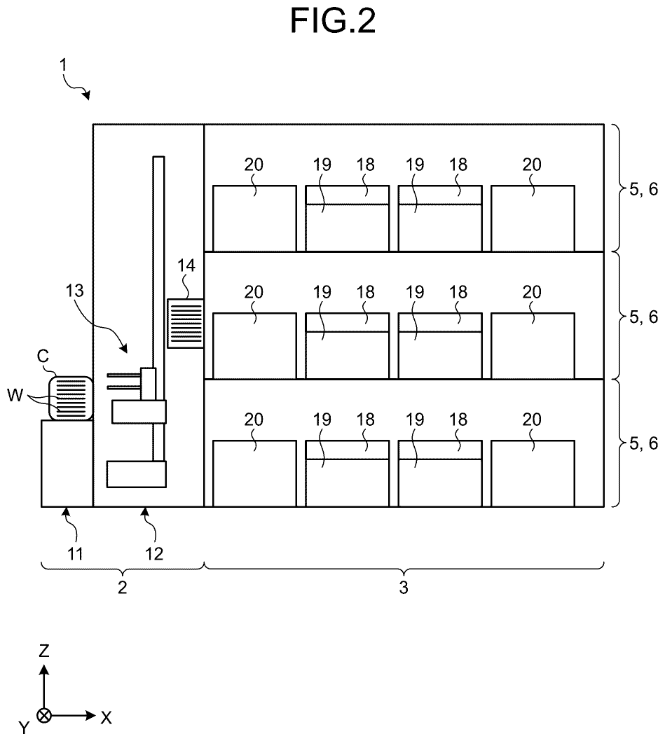

A configuration of the substrate processing system (one example of the substrate processing apparatus) according to the embodiment will be described with reference to FIG. 1 and FIG. 2. FIG. 1 is a schematic cross-sectional view of the substrate processing system viewed from the above of the system according to the embodiment. FIG. 2 is a schematic cross-sectional view of the substrate processing system viewed from the side of the system according to the embodiment.

As illustrated in FIG. 1, a substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. In the carrier placing section 11, a plurality of carriers C are placed to horizontally accommodate a plurality of substrates, namely, semiconductor wafers (hereinafter referred to as “wafer W”).

The transfer section 12 is provided adjacent to the carrier placing section 11. A substrate transfer device 13 and a delivery unit 14 (i.e., deliverer) are placed inside of the transfer section 12.

The substrate transfer device 13 includes a wafer holding mechanism configured to hold the wafer W. The substrate transfer device 13 is movable horizontally and vertically and is pivotable around the vertical axis, and transfers the wafer W between the corresponding carrier C and the delivery unit 14 by using the wafer holding mechanism. The delivery unit 14 is capable of measuring a weight of the wafer W before forming a liquid film thereon by a liquid processing unit 17 (i.e., liquid processor) that will be described hereinafter. Furthermore, the delivery unit 14 is capable of measuring the weight of the wafer W after finishing the drying process of the liquid film by a drying unit 19 that will be described hereinafter.

The processing station 3 is provided adjacent to the transfer section 12. The processing station 3 includes a transfer block 4, a first processing block 5, and a second processing block 6.

The transfer block 4 includes a transfer area 15 and a transfer device 16. The transfer area 15 is, for example, an area having a rectangular parallelpiped shape along the arrangement direction (X-axis direction) of the carry-in/out station 2 and the processing station 3. The transfer device 16 is located in the transfer area 15.

The transfer device 16 includes a wafer holding mechanism 16a, as one example of the substrate holding unit (i.e., substrate holder), for holding the wafer W. The transfer device 16 is capable of moving along the horizontal and vertical directions and turning around the vertical axis. The transfer device 16 transfers the wafer W between the delivery unit 14, a first processing block 5 and a second processing block 6 using the wafer holding mechanism 16a.

The first processing block 5 and the second processing block 6 are arranged adjacent to the transfer area 15 at respective sides of the transfer area 15. As one example, the first processing block 5 is arranged at one side (a positive direction side in the Y-axis direction) of the transfer area 15 in the direction (the Y-axis direction) that is perpendicular to the arrangement direction (the X-axis direction) of the carry-in/out station 2 and the processing station 3. The second processing block 6 is arranged at the other side (a negative direction side in the Y-axis direction) of the transfer area 15 in the direction (the Y-axis direction) that is perpendicular to the arrangement direction (the X-axis direction) of the carry-in/out station 2 and the processing station 3.

As illustrated in FIG. 2, a plurality of the first processing block 5 and a plurality of the second processing block 6 are arranged in a multistage structure along the vertical direction. Although both of the plurality of the first processing block 5 and the plurality of the second processing block 6 have a three-layer multistage structure according to the embodiment, the number of the layers of the plurality of the first processing block 5 and the plurality of the second processing block 6 shall not limited to three.

As described above, the plurality of the first processing block 5 and the plurality of the second processing block 6 can be arranged in a multistage structure at both sides of the transfer block 4 of the substrate processing system 1 in the embodiment. The transfer of the wafer W between the first processing block 5 and the second processing block 6 arranged in each of the layers and the delivery unit 14 can be executed by the single transfer device 16 arranged in the transfer block 4.

The first processing block 5 includes the liquid processing unit 17.

The liquid processing unit 17 executes a cleaning process for cleaning an upper surface that is a pattern-formed surface of the wafer W. The liquid processing unit 17 also executes a liquid-film forming process for forming a liquid film on the upper surface of the wafer W after the cleaning process. The configuration of the liquid processing unit 17 will be described later.

The second processing block 6 includes a measurement unit 18 (measurer), a drying unit 19 as one example of the process unit (i.e., process mechanism), and a supply unit 20.

The measurement unit 18 measures a weight of the wafer W before and after the liquid-film forming process. The configuration of the measurement unit 18 will be described later.

The drying unit 19 executes a supercritical drying process to the wafer W after the liquid-film forming process. Specifically, the drying unit 19 makes the wafer W after the liquid-film forming process contact with processing liquid that is in the supercritical state so as to dry the wafer W. The configuration of the drying unit 19 will be described later.

The supply unit 20 supplies the processing liquid to the drying unit 19. Specifically, the supply unit 20 includes a group of supplying equipment including such as a flow meter, a flow controller, a back pressure valve and a heater and a housing for accommodating the group of supplying equipment. In the embodiment, the supply unit 20 supplies CO2 as the processing liquid to the drying unit 19.

As illustrated in FIG. 2, the measurement unit 18 and the drying unit 19 are arranged in the vertical direction. As one example, the measurement unit 18 is arranged on the drying unit 19. The measurement unit 18 can be arranged under the drying unit 19. An installation area of the second processing block 6 is reduced since the measurement unit 18 and the drying unit 19 are arranged in the vertical direction.

The substrate processing system 1 includes a control device 7. The control device 7 is, for example, a computer including a controller 71 (i.e., circuitry) and a storage 72.

The controller 71 includes a microcomputer including a Central Processing Unit (CPU), a Read Only Memory (ROM), a Random Access Memory (RAM), an input/output port and the like, and variety of circuits. The CPU of the microcomputer reads out and executes a program stored in the ROM so as to control the transfer devices 13 and 16, the liquid processing unit 17, the drying unit 19, the supply unit 20 and the like.

The program may be recorded in a computer-readable recording medium and thus may be installed into the storage 72 of the control device 7 from the recording medium. The computer-readable recording medium includes, for example, a hard disk (HD), a flexible disk (FD), a compact disc (CD), a magneto-optical disk (MO), a memory card and the like.

The storage 72 is realized by, for example, RAM, a semiconductor memory device such as a flash memory, or a recording medium such as a hard disk or an optical disc.

### Transfer Flow

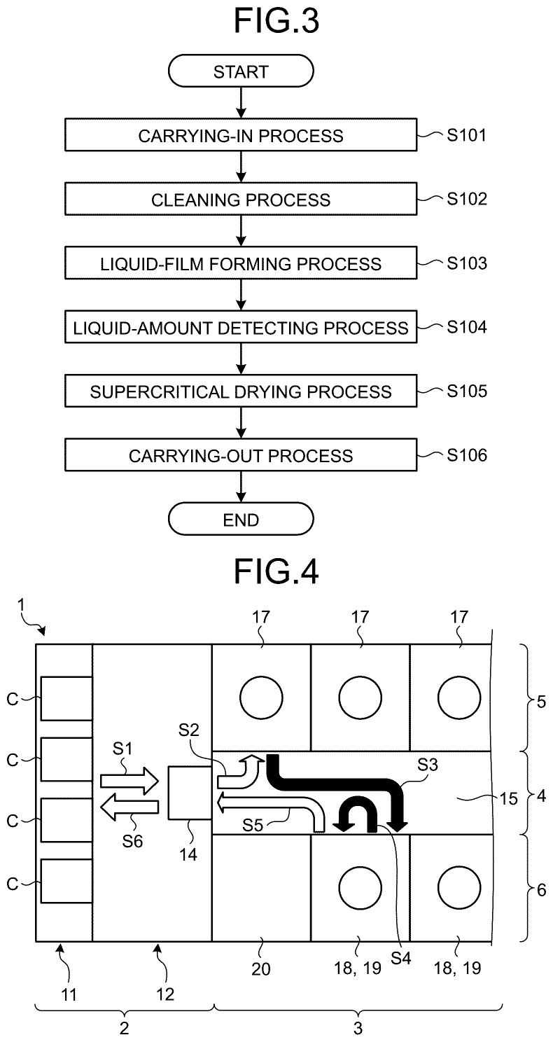

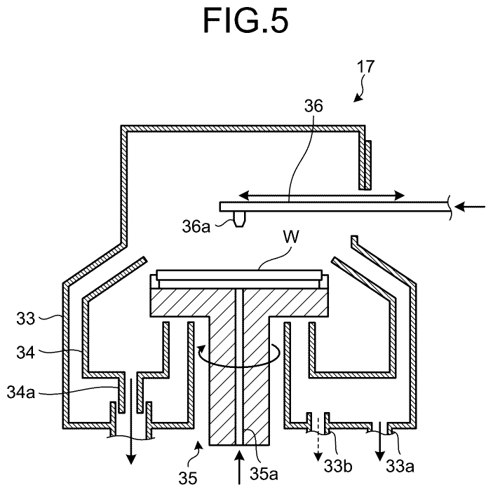

A transfer flow of the wafer W according to the above-mentioned substrate processing system 1 will be described with reference to FIG. 3 and FIG. 4. FIG. 3 is a flowchart illustrating a series of substrate processing procedures to be executed in the substrate processing system 1 according to the embodiment. FIG. 4 is a diagram illustrating procedures of the wafer transfer according to the embodiment. It is to be noted that the series of substrate processing procedures illustrated in FIG. 3 are executed under the control of the controller 71. Furthermore, a transfer position adjusting process for adjusting the transfer position of the wafer W by the transfer device 16 is executed before the series of substrate processing procedures illustrated in FIG. 3. The transfer position adjusting process will be described later.

As illustrated in FIG. 3, the substrate processing system 1 firstly executes a carrying-in process (Step S101). In the carrying-in process, the transfer device 13 (see FIG. 1) takes out the wafer W from the carrier C and places it on the delivery unit 14 (see the procedure S1 in FIG. 4). The delivery unit 14 includes a weight measuring device such as a load cell. The delivery unit 14 measures the weight of the wafer W before forming the liquid film by the liquid processing unit 17 by using the measuring device. Subsequently, the transfer device 16 (see FIG. 1) takes out the wafer W from the delivery unit 14 and carries it in the liquid processing unit 17 (see the procedure S2 in FIG. 4).

Next, the substrate processing system 1 executes a cleaning process in the liquid processing unit 17 (Step S102). The liquid processing unit 17 supplies various kinds of processing liquids on an upper surface, that is a pattern-formed surface, of the wafer W so as to remove a particle, a natural oxide film and the like from the upper surface of the wafer W.

Next, the substrate processing system 1 executes a liquid-film forming process in the liquid processing unit 17 (Step S103). The liquid processing unit 17 supplies a liquid state isopropyl alcohol (hereinafter referred to as “IPA liquid”) on the upper surface of the wafer W after the cleaning process so as to form a liquid film of the IPA liquid on the upper surface of the wafer W.

The wafer W after the liquid-film forming process is transferred from the liquid processing unit 17 to the measurement unit 18 by the transfer device 16 (the procedure S3 in FIG. 4).

Next, a liquid-amount detecting process is executed in the substrate processing system 1 by using the measurement unit 18 (Step S104). The measurement unit 18 measures the weight of the wafer W after the liquid-film forming process. The controller 71 calculates the difference between the weight of the wafer W before the liquid-film forming process measured by the delivery unit 14 and the weight of the wafer W after the liquid-film forming process measured by the measurement unit 18 so as to detect the liquid amount of the liquid film formed on the wafer W based on the calculated difference.

Then, a determination process for determining whether the liquid amount of the liquid film formed on the wafer W is normal or not is executed in the substrate processing system 1. In the determination process, the controller 71 determines whether the liquid amount of the liquid film formed on the wafer W is within a predetermined permissible range or not. The permissible range is a range in which a pattern collapse to cause a defective wafer and a defect such as a particle do not occur to the wafer W after the supercritical drying process. The controller 71 allows the execution of the supercritical drying process in a case where the liquid amount of the liquid film formed on the wafer W is within the predetermined permissible range. The controller 71 may stop the execution of the supercritical drying process with an output of an alert in a case where the liquid amount of the liquid film formed on the wafer W is outside of the predetermined permissible range.

In a case where the execution of the supercritical drying process is allowed, the wafer W transferred to the measurement unit 18 after the liquid-film forming process is transferred from the measurement unit 18 to the drying unit 19 (the procedure S4 in FIG. 4). Then, the substrate processing system 1 executes the supercritical drying process at the drying unit 19 (Step S105). In the supercritical drying process, the drying unit 19 makes the wafer W after the liquid-film forming process contact with the processing liquid that is under the supercritical state so as to dry the wafer W after the liquid-film forming process.

Next, the substrate processing system 1 executes a carrying-out process (Step S106). In the carrying-out process, the transfer device 16 takes out the wafer W after the supercritical drying process from the drying unit 19 and transfers it to the delivery unit 14 (see the procedure S5 in FIG. 4). Subsequently, the transfer device 13 takes out the wafer after the supercritical drying process from the delivery unit 14 and transfers it to the carrier C (see the procedure S6 in FIG. 4). A series of the substrate processing regarding one wafer W ends by completing the carrying-out process.

### Configuration of Liquid Processing Unit

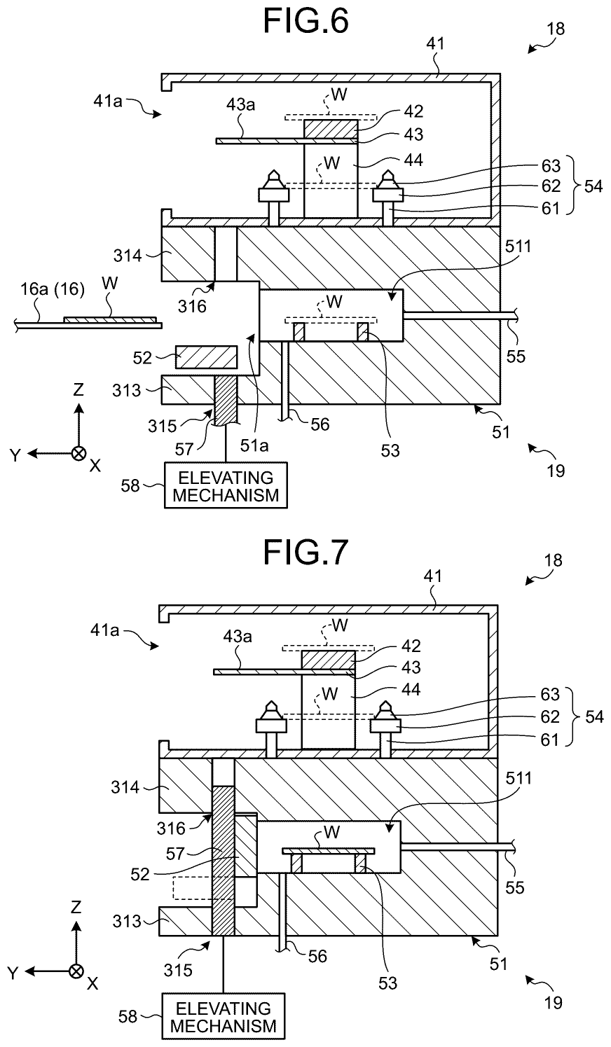

A configuration of the liquid processing unit 17 will be described with reference to FIG. 5. FIG. 5 is a diagram illustrating a configuration example of the liquid processing unit 17 according to the embodiment. The liquid processing unit 17 is, for example, a single wafer processing cleaner that cleans the wafer one by one by spin cleaning.

As illustrated in FIG. 5, the liquid processing unit 17 horizontally holds the wafer W with a wafer holding mechanism 35 arranged in an outer chamber 33 which forms a processing space, and rotates the wafer W by rotating the wafer holding mechanism 35 around the vertical axis. The liquid processing unit 17 allows a nozzle arm 36 to enter above the rotating wafer W and supplies chemical liquid and rinse liquid in a predetermined order from a chemical liquid nozzle 36a provided at a leading end of the nozzle arm 36 so as to execute the cleaning process of the upper surface of the wafer W.

A chemical liquid supply route 35a is formed at an inner part of the wafer holding mechanism 35 of the liquid processing unit 17. The lower surface of the wafer W is also cleaned by chemical liquid and rinse liquid supplied from the chemical liquid supply route 35a.

The cleaning process is executed by, for example, removing a particle and an organic contaminant first by using SC1 (mixed solution of ammonia and hydrogen peroxide) that is alkaline chemical liquid, and a rinse cleaning is executed thereafter by using deionized water (hereinafter referred to as “DIW”) that is rinse liquid. Next, a natural oxide film is removed by diluted hydrofluoric acid (hereinafter referred to as “DHF”) that is acid chemical liquid, and a rinse cleaning by DIW is executed thereafter.

The above-mentioned various chemical liquids are received by an outer chamber 33 and an inner cup 34 arranged in the outer chamber 33, and discharged from a drain port 33a provided at the bottom of the outer chamber 33 and a drain port 34a provided at the bottom of the inner cup 34. Furthermore, the atmosphere in the outer chamber 33 is exhausted from an exhaust port 33b provided at the bottom of the outer chamber 33.

The liquid-film forming process is executed after the rinsing process of the cleaning process. Specifically, the liquid processing unit 17 supplies the IPA liquid to an upper surface and a lower surface of the wafer W while rotating the wafer holding mechanism 35. Accordingly, the DIW remaining on both surfaces of the wafer W is replaced with the IPA. Next, the liquid processing unit 17 stops rotating the wafer holding mechanism 35 in a gently manner.

The wafer W after the liquid-film forming process is transferred to the transfer device 16 by a transfer mechanism not illustrated provided on the wafer holding mechanism 35 under the state that the IPA liquid film is formed on the upper surface of the wafer W, and transferred out from the liquid processing unit 17. The liquid film formed on the wafer W prevents from generating a pattern collapse caused by evaporating the liquid (vaporization) on the upper surface of the wafer W during the transfer of the wafer W to the measurement unit 18 from the liquid processing unit 17 or the carry-in operation to the measurement unit 18. Furthermore, the liquid film formed on the wafer W prevents from generating a pattern collapse caused by evaporating the liquid (vaporization) on the upper surface of the wafer W during the transfer of the wafer W to the drying unit 19 from the measurement unit 18 or the carry-in operation to the drying unit 19.

### Configuration of Measurement Unit and Drying Unit

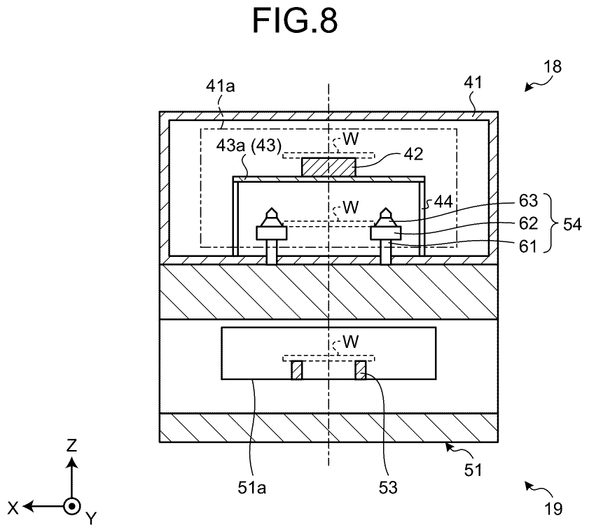

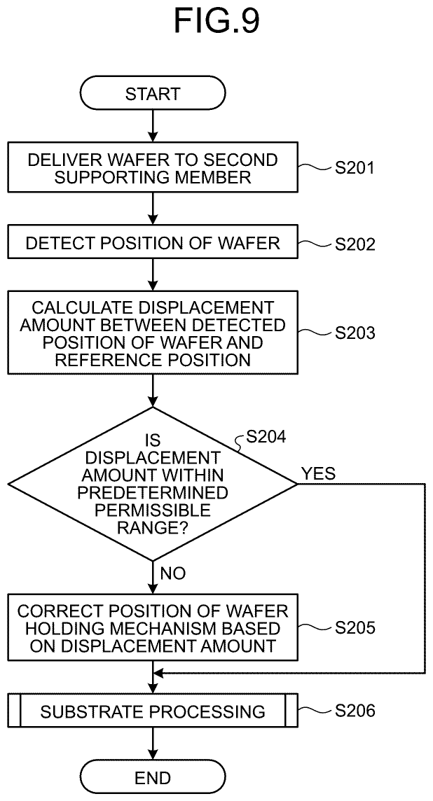

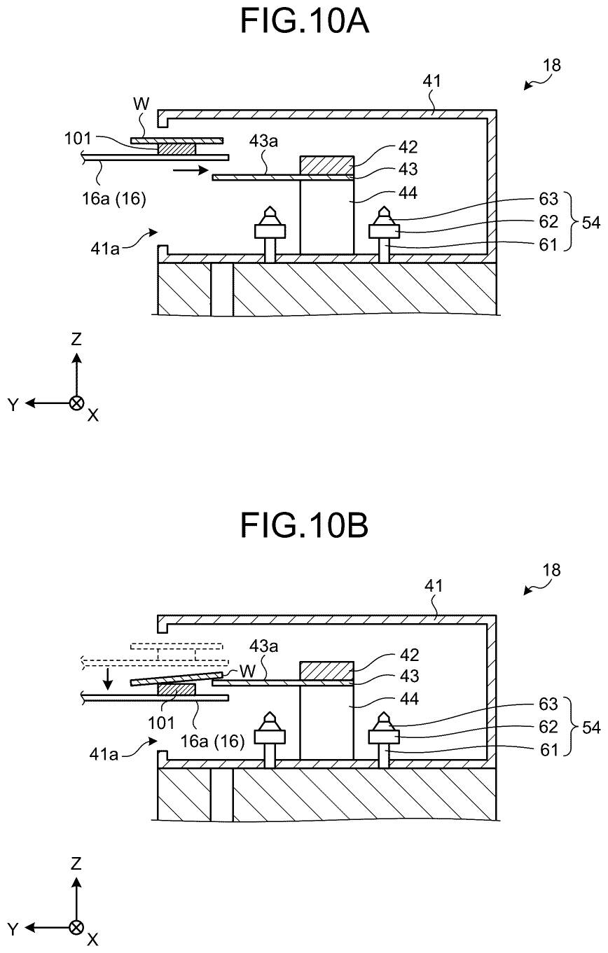

Next, configurations of the measurement unit 18 and the drying unit 19 will now be described with reference to FIGS. 6 to 8. FIG. 6 is a schematic cross-sectional view illustrating a configuration of the measurement unit 18 and the drying unit 19 according to the embodiment. FIG. 7 is a schematic cross-sectional view illustrating one example of a state where the wafer W is housed in a processing container 51 of the drying unit 19. FIG. 8 is a schematic cross-sectional side view of the processing container 51 of the drying unit 19 viewed from the side of an opening 51a.

First of all, a configuration of the drying unit 19 is explained. As illustrated in FIGS. 6 and 7, the drying unit 19 includes the processing container 51, a lid 52, a first supporting member 53, and a second supporting member 54.

The processing container 51 is a pressure container which is capable of creating a high-pressure environment such as 16 to 20 Mpa and the like. The processing container 51 arranged at the negative direction side in the Y-axis direction of the transfer area 15 (See FIG. 1). The supercritical drying process is executed in a processing space 511 in the processing container 51. The processing container 51 has a rectangular shape in a plan view and the opening 51a to be used for carrying-in/out the wafer W is provided on one of four surfaces that is opposite to the transfer area 15.

The lid 52 is connected to a rotation mechanism and a moving mechanism not illustrated, and capable of moving and rotating between a closing position and a standby position by the rotation mechanism and the moving mechanism. The closing position is a position where the lid 52 closes the opening 51a. The standby position is a position where the lid 52 opens the opening 51a and where the carry-in/out path of the wafer W to the opening 51a is not interfered.

The first supporting member 53 horizontally supports the wafer W in the processing container 51. The first supporting member 53 includes supporting pins which are provided on a bottom surface inside the processing container 51 for supporting the wafer W from below.

The second supporting member 54 horizontally supports the wafer W outside the processing container 51. The second supporting member 54 is used for a transfer position adjusting process for adjusting the transfer position of the wafer W to be transferred by the transfer device 16. The second supporting member 54 is provided on an outer surface of the processing container 51 in the vertical direction (an upper surface of the processing container 51). The second supporting member 54 may be provided on a lower surface of the processing container 51. A part of the second supporting member 54 is located in the measurement unit 18.

According to the embodiment, as illustrated in FIG. 8, the first supporting member 53 and the second supporting member 54 support the wafer W in such a manner that a position of a center axis of the wafer W inside the processing container 51 in a horizontal direction (X-axis direction) matches a position of a center axis of the wafer W outside of the processing container 51 in the horizontal direction (X-axis direction) at least in a case where viewed from the carry-in/out direction (Y-axis direction) of the wafer W to/from the processing container 51. In other words, the first supporting member 53 and the second supporting member 54 support the wafer W in such a manner that the center axis of the wafer W when the wafer is located inside of the processing container 51 matches the center axis of the wafer W when the wafer is located outside of the processing container 51 at least in a side view viewed from the opening 51a of the processing container 51. Accordingly, a relative positional displacement of the wafer W between the inside and the outside of the processing container 51 can be reduced since the center axis of the wafer W supported by the first supporting member 53 matches the center axis of the wafer W supported by the second supporting member 54. If the center axis of the wafer W inside the processing container 51 does not match the center axis of the wafer W outside of the processing container 51, a turn operation around the vertical axis is necessary for the transfer device 16 when the wafer W after the liquid-film forming process is transferred from the measurement unit 18 to the drying unit 19. On the contrary, such turn operation is not required according to the embodiment. Accordingly, a possibility that the liquid film formed on the upper surface of the wafer W is scattered off due to the turn operation around the vertical axis can be reduced.

Furthermore, according to the embodiment, the first supporting member 53 is provided on the bottom inside the processing container 51. Accordingly, vibration of the first supporting member 53 can be reduced if compared with providing the first supporting member 53 on the lid 52. Therefore, a possibility that the liquid film formed on the upper surface of the wafer W drops due to the vibration of the first supporting member 53 can be reduced according to the embodiment.

Besides, the second supporting member 54 is provided on the outer surface of the processing container 51 in the vertical direction according to the embodiment, the transfer position of the wafer W transferred by the transfer device 16 near the drying unit 19 can be adjusted. Accordingly, the relative positional displacement of the wafer W between the inside and the outside of the processing container 51 can be reduced further according to the embodiment.

Furthermore, the second supporting member 54 is provided on each of a plurality of the processing containers 51 of a plurality of the drying units 19 according to the embodiment. Accordingly, the relative positional displacement of the wafer W between the inside and the outside of the processing container 51 can be reduced for each of the containers 51 of the plurality of the drying units 19 according to the embodiment.

The second supporting member 54 includes four columns 61, four supporting tables 62 and four guide members 63. The four columns 61 are provided on the outer surface of the processing container 51 (that is, the upper surface of the processing container 51 in the embodiment) such that the four columns 61 are vertically extended from the outer surface of the processing container 51. The supporting table 62 has a flat and circular shape to be provided on each of the plurality of columns 61.

The guide member 63 is provided on the supporting table 62. The guide member 63 has a circular shape in its planar view and has a taper upwardly in its side view. The tip of the column 61 protrudes from the upper surface of the guide member 63. The peripheral edge of the bottom of the guide member 63 is located inner than the peripheral edge of the supporting table 62. Accordingly, a part of the upper surface of the supporting table 62 can support the peripheral edge of the wafer W from underneath. The guide member 63 receives the wafer W at its side from the wafer holding mechanism 16a of the transfer device 16, and guides the received wafer W towards the supporting table 62. Accordingly, the guide member 63 can bring the wafer W closer to a predetermined reference position. The reference position is a predetermined position of the wafer W where the center axis of the wafer W inside the processing container 51 matches the center axis of the wafer W outside of the processing container 51.

The processing container 51 includes a supply unit 55 and a discharge unit 56. The supply unit 55 is connected to a group of supplying equipment of the supply unit 20 (see FIG. 1) to supply processing liquid supplied from the supply unit 20 to the processing space 511. The discharge unit 56 discharges processing liquid from the processing space 511.

The supply unit 55 is provided on the processing space 511 of the processing container 51 at a side opposite to the opening 51a. The supply unit 55 supplies the processing liquid in a horizontal direction toward the processing space 511 through a supply port provided at a side of the processing space 511.

The discharge unit 56 is provided on a bottom surface of the processing space 511 of the processing container 51. The discharge unit 56 discharges the processing liquid through a discharge port provided at the bottom of the processing space 511.

The drying unit 19 supplies the processing liquid to the processing space 511 from the supply unit 55, and also discharges the processing liquid in the processing space 511 through the discharge unit 56. A damper is provided on a discharge passage for adjusting discharge amount of the processing liquid discharged from the processing space 511. The damper adjusts the discharge amount of the processing liquid by adjusting the pressure in the processing space 511 into a predetermined pressure. Accordingly, the supercritical state of the processing liquid in the processing space 511 is maintained. The processing liquid under the supercritical state may be referred to as “super critical liquid” thereafter.

The processing container 51 includes a first projecting part 313 and a second projecting part 314 which protrude toward the lid opening direction with reference to the opening 51a. The first projecting part 313 protrudes toward the positive direction in the Y-axis direction from a lower portion of the opening 51a. The second projecting part 314 protrudes toward the positive direction in the Y-axis direction from an upper portion of the opening 51a.

A first insertion hole 315 for communicating an upper surface with a lower surface of the first projecting part 313 is formed on the first projecting part 313. A second insertion hole 316 for communicating an upper surface with a lower surface of the second projecting part 314 is formed on the second projecting part 314 at a position opposite to the first insertion hole 315 in the vertical direction, that is above the first insertion hole 315.

The drying unit 19 includes a lock member 57. The lock member 57 is inserted through the first insertion hole 315 formed at the first projecting part 313. An elevating mechanism 58 for moving the lock member 57 along the vertical direction is connected to the lock member 57.

In the above-mentioned drying unit 19, a carrying-in process of the wafer W is executed in the first place. During the carrying-in process, the transfer device 16 delivers the wafer W held by the wafer holding mechanism 16a to the first supporting member 53. Then, the drying unit 19 moves and rotate the lid 52 from an opened position to a closed position. Accordingly, the wafer W supported by the first supporting member 53 is housed in the processing space 511 of the processing container 51, and the processing space 511 turns into a sealed condition with the lid 52 closed.

The drying unit 19 lifts the lock member 57 by using an elevating mechanism 58 such that the lock member 57 is inserted through the second insertion hole 316 formed at the second projecting part 314.

The lock member 57 pushes the lid 52 on toward the processing space 511 against the internal pressure caused by the processing liquid supplied to the processing space 511. Accordingly, the processing space 511 is maintained under the sealed state with the lid 52.

Next, the drying unit 19 executes a pressure increasing treatment. In the pressure increasing treatment, the drying unit 19 supplies the processing liquid to the processing space 511 of the processing container 51 from the supply unit 55 such that the pressure in the processing space 511 increases. Accordingly, the pressure in the processing space 511 increases from the atmospheric pressure up to a target processing pressure. The target processing pressure, for example, around 16 MPa, is greater than critical pressure that is approximately 7.2 MPa, which makes CO2 as the processing liquid into supercritical state. According to the pressure increasing treatment, the processing liquid in the processing space 511 changes its phase into the supercritical state, and IPA liquid starts to dissolve into the processing liquid under the supercritical state. It's to be noted that the processing liquid supplied from the supply unit 20 may be either one of supercritical state and liquid state.

Then, the drying unit 19 executes a flow treatment. In the flow treatment, the drying unit 19 discharges the processing liquid supplied to the processing space 511 from the discharge unit 56 to the outside of the processing space 511 while keeping the pressure of the processing space 511 as the target processing pressure and supplying the processing liquid to the processing space 511 from the supply unit 55. Accordingly, a streamline flow of the processing liquid which flows around the wafer W in a certain direction is formed.

IPA liquid on a pattern-formed surface (an upper surface) of the wafer W gradually dissolves in the supercritical fluid which is in a high pressure state (for example, 16 MPa) by contacting the supercritical fluid, and is finally replaced by the supercritical fluid. Accordingly, the gap between the pattern turns into a state that is filled with the supercritical fluid.

Next, the drying unit 19 executes a pressure-reducing treatment. In the pressure-reducing treatment, the drying unit 19 reduces the pressure in the processing space 511 from the high pressure state to the atmospheric pressure. Accordingly, the supercritical fluid filled in the gap between the pattern turns into the normal processing liquid which is in a gas state. Thus, IPA liquid between the pattern is removed to complete the drying process of the wafer W.

Although IPA liquid as liquid for preventing from drying and CO2 as the processing liquid are used in the embodiment, any liquid for preventing from drying other than IPA and any liquid other than CO2 as the processing liquid can be used instead.

Next, a configuration of the measurement unit 18 will be explained. As illustrated in FIGS. 6 and 7, the measurement unit 18 includes a case 41, a third supporting member 42, a base member 43, and a supporting member 44. An opening 41a for carrying-in/out the wafer W by the transfer device 16 is formed at the case 41.

The third supporting member 42, such as a load cell, measures the weight of the wafer W by holding the wafer W horizontally. Specifically, the third supporting member 42 measures the weight of the wafer W on which the liquid film is formed by the liquid processing unit 17 and before being housed in the processing container 51. The third supporting member 42 outputs a signal regarding the measured weight of the wafer W to the controller 71.

The base member 43 is provided at a lower portion of the third supporting member 42. The base member 43 is arranged above the second supporting member 54 which is located through the bottom portion of the case 41. The base member 43 includes a projecting part 43a which protrudes toward the opening 41a and closer to the opening 41a than the second supporting member 54. The projecting part 43a is utilized for a transfer position adjusting process using the second supporting member 54.

The supporting member 44 is provided from the bottom portion of the third supporting member 42 and up to a position higher than the second supporting member 54, for supporting the base member 43 from below.

The third supporting member 42 is provided for each of the processing containers 51 of a plurality of drying units 19 via the base member 43 and the supporting member 44. Accordingly, the weight of the wafer W before being housed in each of the processing containers 51 of the plurality of drying units 19 can be individually measured.

### Transfer Position Adjusting Process

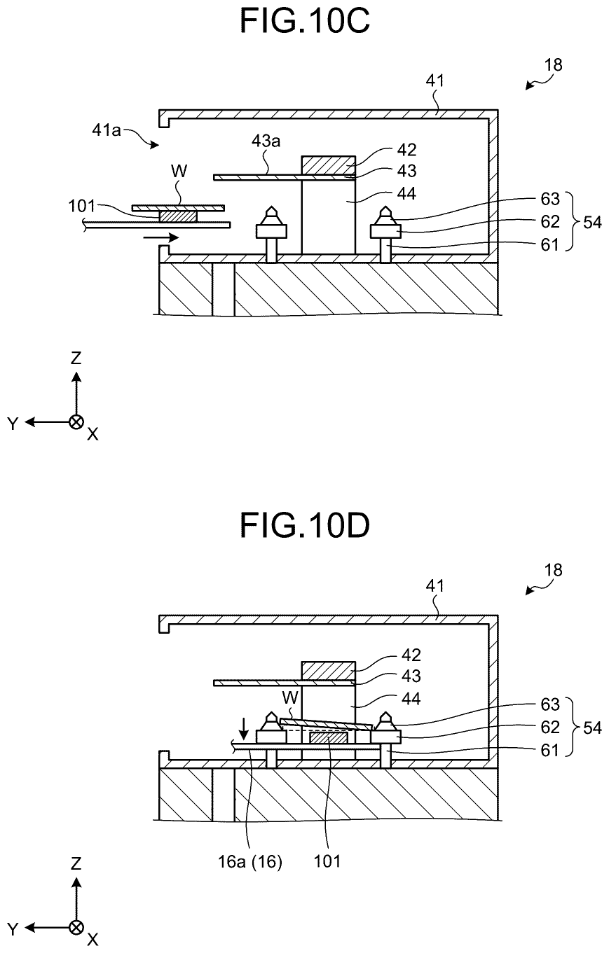

Next, a series of operations including a transfer position adjusting process to be executed by the substrate processing system 1 according to the embodiment will now be described with reference to FIG. 9. FIG. 9 is a flowchart illustrating a procedure of a series of operations to be executed by the substrate processing system 1 according to the embodiment.

As illustrated in FIG. 9, the controller 71 transfers the wafer W from the carrier C to the drying unit 19 via the delivery unit 14 by using the transfer devices 13 and 16, and delivers the wafer W from the wafer holding mechanism 16a to the second supporting member 54 (Step S201). Accordingly, the peripheral edge of the wafer W contacts the guide member 63 of the second supporting member 54 such that the wafer W is guided toward the supporting table 62 by the guide member 63. Thus, the position of the wafer W gets close to a predetermined reference position.

The controller 71 elevates the wafer holding mechanism 16a and lifts up the wafer W from the second supporting member 54. It's to be noted that the wafer holding mechanism 16a is equipped with a position sensor (not illustrated as an example of a detector) for detecting a position of the wafer W held by the wafer holding mechanism 16a.

The controller 71 detects the position of the wafer W by using the position sensor of the wafer holding mechanism 16a (Step S202).

The controller 71 calculates displacement amount between the detected position of the wafer W and the reference position (Step S203).

The controller 71 determines whether the displacement amount is within a predetermined permissible range or not (Step S204). In a case where the displacement amount is within the predetermined permissible range (Yes in Step S204), the controller 71 executes the substrate processing without correcting the position of the wafer holding mechanism 16a (Step S206). The substrate processing in Step S206 corresponds to the substrate processing illustrated in FIG. 3.

On the other hand, in a case where the displacement amount is not within the predetermined permissible range (No in Step S204), the controller 71 corrects the position of the wafer holding mechanism 16a based on the displacement amount (Step S205) and executes the substrate processing thereafter (Step S206).

According to the embodiment, the controller 71 controls the transfer device 16 such that the wafer W is delivered, based on the corrected position of the wafer holding mechanism 16a, from the wafer holding mechanism 16a to the first supporting member 53 during the transfer of the wafer W to the drying unit 19. For example, the controller 71 controls the transfer device 16 based on the corrected position of the wafer holding mechanism 16a in a case where the wafer W after the liquid-film forming process is transferred from the measurement unit 18 to the drying unit 19 (the procedure S4 in FIG. 4). Thus, the wafer transfer from the measurement unit 18 to the drying unit 19 can be executed under the condition that the transfer position of the wafer W to the drying unit 19 is appropriately adjusted.

Furthermore, the controller 71 controls the transfer device 16 such that the wafer W is delivered, based on the corrected position of the wafer holding mechanism 16a, from the wafer holding mechanism 16a to the third supporting member 42 during the transfer of the wafer W to the measurement unit 18. For example, the controller 71 controls the transfer device 16 based on the corrected position of the wafer holding mechanism 16a in a case where the wafer W after the liquid-film forming process is transferred from the liquid processing unit 17 to the measurement unit 18 (the procedure S3 in FIG. 4). Thus, the wafer transfer from the liquid processing unit 17 to the measurement unit 18 can be executed under the condition that the transfer position of the wafer W to the measurement unit 18 is appropriately adjusted.

Furthermore, the controller 71 controls the transfer device 16 such that the wafer W is delivered, by using the wafer holding mechanism 16a without turning the wafer holding mechanism 16a in the horizontal direction, from the third supporting member 42 to the first supporting member 53 during the transfer of the wafer W from the measurement unit 18 to the drying unit 19. Accordingly, a possibility of the liquid film formed on the upper surface of the wafer W being shaken off due to the turning operation around the vertical axis can be reduced.

### Another Example of Transfer Position Adjusting Process

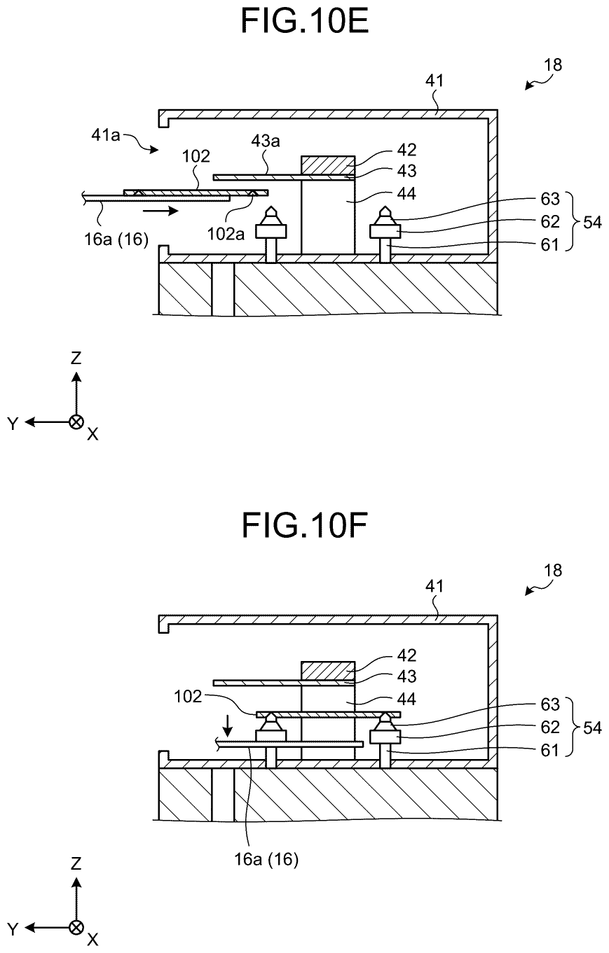

According to the example illustrated in FIG. 9, it is disclosed to correct the position of the wafer holding mechanism 16a based on the displacement amount between the position of the wafer W and the reference position. However, correcting the position of the wafer holding mechanism 16a should not be limited to the example in FIG. 9. For example, the position of the wafer holding mechanism 16a may be corrected more accurately by using various kinds of adjusting members. Another example of transfer position adjusting process to be executed by the substrate processing system 1 according to the embodiment will now be described with reference to FIG. 10A to FIG. 10F. FIG. 10A to FIG. 10F are operation explanatory illustrations illustrating another example of the transfer position adjusting process to be executed by the substrate processing system 1 according to the embodiment.

The transfer device 16 holds, by using the wafer holding mechanism 16a, a vacuum suction member 101 stored in a stocker (not illustrated) in the transfer section 12. The vacuum suction member 101 can fix the lower surface of the wafer W on the wafer holding mechanism 16a by vacuum suction in a case where the wafer W is placed on the vacuum suction member 101. The vacuum suction member 101 includes a pressure sensor for detecting the pressure regarding the vacuum suction, and outputs a signal indicating a detection result detected by the pressure sensor to the controller 71. The controller 71 places and fixes the wafer W on the vacuum suction member 101.

The controller 71 controls the wafer holding mechanism 16a to bring the wafer W placed on the vacuum suction member 101 into the case 41 of the measurement unit 18 as illustrated in FIG. 10A.

The controller 71 lowers the wafer holding mechanism 16a as illustrated in FIG. 10B. Accordingly, the wafer W placed on the vacuum suction member 101 contacts the projecting part 43a of the base member 43 and is detached from the vacuum suction member 101. In a case where the wafer W is detached from the vacuum suction member 101, the detection result of the pressure sensor of the vacuum suction member 101 changes. The controller 71 corrects the position of the wafer holding mechanism 16a in the Z-axis direction to certain height which does not generate interference between the wafer W and the base member 43 according to the position of the height in a case where the detected result of the pressure sensor of the vacuum suction member 101 changes.

The controller 71 elevates the wafer holding mechanism 16a such that the wafer W is placed on and fixed to the vacuum suction member 101. The controller 71 controls the wafer holding mechanism 16a to move the wafer W placed on the vacuum suction member 101 out of the case 41 of the measurement unit 18.

The controller 71 moves the wafer W placed on the vacuum suction member 101 into the case 41 of the measurement unit 18 according to the corrected position of the wafer holding mechanism 16a as illustrated in FIG. 10C.

The controller 71 lowers the wafer holding mechanism 16a as illustrated in FIG. 10D. Accordingly, the wafer W placed on the vacuum suction member 101 makes a contact with the guide member 63 of the second supporting member 54 such that the wafer W is detached from the vacuum suction member 101. In a case where the wafer W is detached from the vacuum suction member 101, the detection result of the pressure sensor of the vacuum suction member 101 changes. The controller 71 corrects the position of the wafer holding mechanism 16a in the Z-axis direction such that the wafer W can be received by the second supporting member 54 according to the position of the height in a case where the detected result of the pressure sensor of the vacuum suction member 101 changes. Furthermore, the wafer W detached from the vacuum suction member 101 is guided toward the supporting table 62 by the guide member 63. Accordingly, the position of the wafer W gets closer to the predetermined reference position.

The controller 71 elevates the wafer holding mechanism 16a such that the wafer W is lifted from the second supporting member 54. The wafer holding mechanism 16a includes a position sensor not illustrated as one example of the detector for detecting the position of the wafer W held by the wafer holding mechanism 16a.

The controller 71 controls the position sensor of the wafer holding mechanism 16a to detect the position of the wafer W in the X-axis direction and the Y-axis direction. The controller 71 calculates the displacement amount between the detected position of the wafer W and the reference position. Then, the controller 71 corrects the position of the wafer holding mechanism 16a based on the calculated displacement amount.

The transfer device 16 holds a positioning substrate 102 stored in a stocker (not illustrated) in the transfer section 12 by using the wafer holding mechanism 16a. The positioning substrate 102 includes four guide grooves 102a provided at four locations corresponding to four columns 61 of the second supporting member 54. Each of the guide grooves 102a has a tapered inner surface to guide the tip of the column 61 such that the positioning substrate 102 moves along the inner surface. According to the guide groove 102a, the position of the positioning substrate 102 can become closer to the predetermined reference position.

The controller 71 moves the positioning substrate 102 held by the wafer holding mechanism 16a into the case 41 of the measurement unit 18 according to the corrected position of the wafer holding mechanism 16a as illustrated in FIG. 10E.

The controller 71 lowers the wafer holding mechanism 16a as illustrated in FIG. 10F. Accordingly, the positioning substrate 102 makes a contact with the tip of the column 61 at the tapered inner surface of the guide groove 102a such that the positioning substrate 102 is separated from the wafer holding mechanism 16a. The positioning substrate 102 separated from the wafer holding mechanism 16a moves along the tapered inner surface of the guide groove 102a. Accordingly, the position of the positioning substrate 102 gets close to the predetermined reference position.

The controller 71 elevates the wafer holding mechanism 16a such that the positioning substrate 102 is lifted from the second supporting member 54. The wafer holding mechanism 16a includes a position sensor not illustrated as one example of the detector for detecting the position of the positioning substrate 102 held by the wafer holding mechanism 16a.

The controller 71 controls the position sensor of the wafer holding mechanism 16a to detect the position of the positioning substrate 102 in the X-axis direction and the Y-axis direction. The controller 71 calculates the displacement amount between the detected position of the positioning substrate 102 and the reference position. Then, the controller 71 corrects the position of the wafer holding mechanism 16a based on the calculated displacement amount.

According to the substrate processing system 1 of the embodiment, the position of the wafer holding mechanism 16a is corrected in two stages by using the positioning substrate, that is, the vacuum suction member 101 and the positioning substrate 102. Accordingly, the position of the wafer holding mechanism 16a can be corrected more accurately.

As described in the above, the substrate processing system 1 as one example of a substrate processing apparatus includes the drying unit 19 as one example of a process unit (the process unit can also be referred to as a process mechanism or the like) for processing the wafer W as one example of a substrate. The process unit includes the processing container 51 as one example of a processing container for accommodating the substrate, the first supporting member 53 as one example of a first supporting member for horizontally supporting the substrate in the processing container, and the second supporting member 54 as one example of a second supporting member for horizontally supporting the substrate at the outside of the processing container. The first supporting member and the second supporting member support the substrate such that the center axis of the substrate in the processing container and the center axis of the substrate at the outside of the processing container match in a case where at least viewed from the direction where the substrate is carried-in to the container and carried-out from the container. Accordingly, the relative position displacement of the substrate between the inside and the outside of the processing container can be reduced according to the embodiment.

### An Alternative Example

As an alternative example of the substrate processing system 1, the drying unit 19 may include a lid that is able to open and close an opening provided on an upper or lower portion of the processing container. Accordingly, an easier maintenance of the processing container can be achieved.

According to the substrate processing system 1 of the alternative example, the measurement unit 18 may further measure the weight of the wafer W after finishing the liquid film drying process in the processing container 51, that is, the weight of the wafer w after finishing the supercritical drying process. The delivery unit 14 may further measure the weight of the wafer w after finishing the supercritical drying process. In this case, the controller 71 detects the liquid amount of the liquid film formed on the wafer W based on a difference between the weight of the wafer W after finishing the liquid-film forming process measured by the measurement unit 18 and the weight of the wafer W after finishing the supercritical drying process measured by the measurement unit 18 or the delivery unit 14.

According to the above disclosure, the displacement of the relative position of the substrate between the inside and outside of the processing container can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus comprising:
a process mechanism that includes:
a processing container that accommodates therein a substrate;
a first supporting member that horizontally supports the substrate in the processing container; and
a second supporting member that horizontally supports the substrate at an outside of the processing container, wherein
the first supporting member and the second supporting member support the substrate to align a center axis of the substrate in the processing container with a center axis of the substrate at the outside of the processing container when viewed from a direction where the substrate is carried-in to the container and carried-out from the container.

2. The substrate processing apparatus according to claim 1, further comprising:
a transfer device including a substrate holder, the substrate holder holds the substrate and is configured to transfer the substrate to and from the process mechanism;
a detector configured to detect a position of the substrate held by the substrate holder; and
circuitry configured to:
correct a position of the substrate holder based on a displacement amount of the substrate between a predetermined reference position and a position of the substrate detected by the detector after transferring the substrate to the second supporting member; and
control the transfer device in such a manner that the substrate is transferred from the substrate holder to the first supporting member based on the corrected position of the substrate holder when the substrate is transferred to the process mechanism.

3. The substrate processing apparatus according to claim 2, further comprising:
a measurer configured to measure a weight of the substrate at the outside of the processing container; wherein
the measurer includes a third supporting member that measures the weight of the substrate by horizontally holding the substrate,
the substrate holder is freely movable to transfer the substrate from and to the measurer, and
the circuitry is configured to control the transfer device to transfer the substrate from the substrate holder to the third supporting member based on the corrected position of the substrate holder when the substrate is transferred to the measurer.

4. The substrate processing apparatus according to claim 3, wherein
when the substrate is transferred to the process mechanism from the measurer, the circuitry is further configured to control the transfer device to transfer the substrate from the third supporting member to the first supporting member using the substrate holder without a turning operation in a horizontally direction.

5. The substrate processing apparatus according to claim 1, wherein
the first supporting member is provided on a bottom surface in the processing container.

6. The substrate processing apparatus according to claim 1, wherein
the process mechanism includes a lid that is configured to open and close the processing container, the processing chamber having an opened upper or lower portion, and
the first supporting member is provided on the lid.

7. The substrate processing apparatus according to claim 1, wherein
the second supporting member is provided on an outer surface of the processing container.

8. The substrate processing apparatus according to claim 1, wherein
apparatus includes a plurality of the process mechanisms, and
the second supporting member is provided on each of a plurality of the processing containers of the plurality of the process mechanisms.

9. The substrate processing apparatus according to claim 2, wherein
the second supporting member includes:
a plurality of columns provided on an outer surface of the processing container, the plurality of columns extending vertically from the outer surface of the processing container;
a supporting table provided on each of the plurality of columns; and
a guide member provided on the supporting table and guiding the substrate transferred from the substrate holder toward the predetermined reference position.

10. The substrate processing apparatus according to claim 3, further comprising:
a plurality of the process mechanisms, wherein
the third supporting member is provided on each of a plurality of the processing containers of the plurality of the process mechanisms.

11. The substrate processing apparatus according to claim 3, wherein
before the substrate is housed in the processing container, the measurer is configured to measure the weight of the substrate on which a liquid film is formed.

12. The substrate processing apparatus according to claim 11, wherein
the measurer is further configured to measure the weight of the substrate after executing a drying process of the liquid film in the processing container.

13. The substrate processing apparatus according to claim 2, further comprising:
a deliverer arranged adjacent to a transfer block where the transfer device is located, the substrate being to be placed on the deliverer, wherein
the transfer device transfers the substrate using the substrate holder between the deliverer and a process block where a liquid processor and the process mechanism are arranged,
the liquid processor is configured to form a liquid film, and
the deliverer is configured to measure the weight of the substrate before the liquid film is formed by the liquid processor, or the weight of the substrate after a drying process is executed on the liquid film in the processing container.

14. A transfer position adjusting method to be executed in a substrate processing apparatus including:
a process mechanism the process mechanism including a processing container that accommodates therein a substrate;
a transfer device including a substrate holder that holds the substrate and is freely movable to transfer the substrate to and from the process mechanism; and
a detector configured to detect a position of the substrate held by the substrate holder;
a first supporting member that horizontally supports the substrate in the processing container; and
a second supporting member that horizontally supports the substrate at an outside of the processing container, the method comprising:
correcting a position of the substrate holder based on a displacement amount between a predetermined reference position and a position of the substrate detected by the detector after transferring to the second supporting member; and
controlling the transfer device to transfer the substrate from the substrate holder to the first supporting member based on the corrected position of the substrate holder when the substrate is transferred to the process mechanism.

15. The transfer position adjusting method according to claim 14, further comprising:
measuring, by a measurer, a weight of the substrate at the outside of the processing container
controlling, by circuitry of the substrate processing apparatus, the transfer device to transfer the substrate from the substrate holder to a third supporting member of the measurer based on the corrected position of the substrate holder when the substrate is transferred to the measurer.

16. The transfer position adjusting method according to claim 15, further comprising:
transferring, by the transfer device, the substrate from the measurer to the process mechanism; and
controlling, by the circuitry, the transfer device to transfer the substrate from the third supporting member to the first supporting member by using the substrate holder without a turning operation in a horizontally direction.

17. The transfer position adjusting method according to claim 15, further comprising, before the substrate is housed in the processing container, measuring, by the measurer, the weight of the substrate on which a liquid film is formed.

18. The transfer position adjusting method according to claim 17, further comprising measuring, by the measurer, the weight of the substrate after executing a drying process of the liquid film in the processing container.

19. The transfer position adjusting method according to claim 14, wherein
the process mechanism includes a lid that is able to open and close the processing container, the processing chamber having an opened upper or lower portion, and
the first supporting member is provided on the lid.

20. The transfer position adjusting method according to claim 14, wherein
the second supporting member includes:
a plurality of columns provided on an outer surface of the processing container, the plurality of columns extending vertically from the outer surface of the processing container;
a supporting table provided on each of the plurality of columns; and
a guide member provided on the supporting table and guiding the substrate transferred from the substrate holder toward to the predetermined reference position.
